(19) United States
(12) Patent Application Publication
(10) Pub. No.: US 2024/0088217 A1
(43) Pub. Date: Mar. 14, 2024

(54) BARRIER LAYER FOR DIELECTRIC RECESS MITIGATION

(71) Applicant: Intel Corporation, Santa Clara, CA (US)

(72) Inventors: Tao Chu, Portland, OR (US); Minwoo Jang, Portland, OR (US); Chia-Ching Lin, Portland, OR (US); Yanbin Luo, Portland, OR (US); Ting-Hsiang Hung, Beaverton, OR (US); Feng Zhang, Hillsboro, OR (US); Guowei Xu, Portland, OR (US)

(73) Assignee: Intel Corporation, Santa Clara, CA (US)

(21) Appl. No.: 17/940,195

(22) Filed: Sep. 8, 2022

(51) Int. Cl. H01L 29/06; H01L 21/762; H01L 29/78

(52) U.S. Cl. CPC H01L 29/0649; H01L 21/76224; H01L 29/7856

(57) ABSTRACT

Techniques are provided herein to form semiconductor devices that include a layer across an upper surface of a dielectric fill between devices and configured to prevent or otherwise reduce recessing of the dielectric fill. In this manner, the layer may be referred to as a barrier layer or recess-inhibiting layer. The semiconductor regions of the devices extend above a subfin region that may be native to the substrate. These subfin regions are separated from one another using a dielectric fill that acts as a shallow trench isolation (STI) structure to electrically isolate devices from one another. A barrier layer is formed over the dielectric fill early in the fabrication process to prevent or otherwise reduce the dielectric fill from recessing during subsequent processing. The layer may include oxygen and a metal, such as aluminum.

### FIELD OF THE DISCLOSURE

The present disclosure relates to integrated circuits, and more particularly, to mitigation of recessed dielectric layers adjacent to semiconductor devices.

### BACKGROUND

As integrated circuits continue to scale downward in size, a number of challenges arise. For instance, reducing the size of memory and logic cells is becoming increasingly more difficult, as is reducing device spacing at the device layer. Many processes used to form various structures have unintended consequences that can adversely affect other structures. However, protecting certain structures can be challenging due to the small feature size coupled with the different materials being used. Accordingly, there remain a number of non-trivial challenges with respect to forming the next generation of semiconductor devices.

### BRIEF DESCRIPTION OF THE DRAWINGS

FIGS. 1A and 1B are cross-sectional and plan views, respectively, of some semiconductor devices that illustrate a barrier layer used to protect an underlying dielectric fill, in accordance with an embodiment of the present disclosure.

FIG. 1C is a cross-sectional view of some semiconductor devices that illustrates a recessed dielectric fill, in the absence of a barrier layer in accordance with an embodiment of the present disclosure.

FIGS. 2A-2J′ are cross-sectional views that illustrate various stages in an example process for forming semiconductor devices that use a barrier layer to protect an underlying dielectric fill, in accordance with some embodiments of the present disclosure.

FIG. 3 illustrates a cross-sectional view of a chip package containing one or more semiconductor dies, in accordance with some embodiments of the present disclosure.

FIG. 4 is a flowchart of a fabrication process for semiconductor devices having a barrier layer used to protect an underlying dielectric fill, in accordance with an embodiment of the present disclosure.

FIG. 5 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form semiconductor devices that include a layer across an upper surface of a dielectric fill between devices and configured to prevent or otherwise reduce recessing of the dielectric fill. The techniques can be used in any number of integrated circuit applications and are particularly useful with respect to device layer transistors, such as finFETs or gate-all-around transistors (e.g., ribbonFETs and nanowire FETs). In an example, a semiconductor device includes a conductive material that is part of a transistor gate structure around or otherwise on a semiconductor region. The semiconductor region can be, for example, a fin of semiconductor material that extends between a source region and a drain region, or one or more nanowires or nanoribbons of semiconductor material that extend between a source region and a drain region. The gate structure includes a gate dielectric (e.g., high-k gate dielectric material) and a gate electrode (e.g., conductive material such as workfunction material and/or gate fill metal). The semiconductor region extends above a subfin region that may be native to the substrate. These subfin regions of neighboring devices are separated from one another using a dielectric fill that acts as a shallow trench isolation (STI) structure to electrically isolate devices from one another. According to some embodiments, a layer configured to act as a barrier layer is formed over the dielectric fill early in the fabrication process to prevent the dielectric fill from recessing during subsequent processing. In this manner, the layer acts as a barrier or inhibitor to undesired recessing. A recessed dielectric fill can expose portions of the subfin regions to the gate structure thus increasing parasitic capacitance and hurting the device performance. So avoiding or otherwise reducing such recessing of dielectric fill material can provide benefits. Numerous variations and embodiments will be apparent in light of this disclosure.

### General Overview

As previously noted above, there remain a number of non-trivial challenges with respect to integrated circuit fabrication. In more detail, many transistor structures are subjected to multiple fabrication processes that can include introduction of various aqueous or gaseous compounds and/or temperature changes. Chemicals designed to etch away certain materials could be exposed long enough or at the right conditions to other materials to begin also etching away portions of those other materials. In the case of dielectric isolation structures, such as STI structures between devices, the surfaces of such dielectric structures may end up recessed lower than desired due to any number of fabrication processes occurring over them. Recessed STI structures can expose subfin portions of the semiconductor devices and cause increased parasitic capacitance throughout the integrated circuit.

Thus, and in accordance with an embodiment of the present disclosure, techniques are provided herein to form barrier layers early in the fabrication process to protect dielectric features, such as the STI structures between devices. The barrier layer can act as a robust etch stop layer to protect the underlying dielectric material from any further etching caused by the removal of various other materials above the dielectric material. The barrier layer may be conformally deposited using a chemical vapor deposition (CVD) process, like atomic layer deposition (ALD) and partially removed such that it remains only on the top surfaces of the dielectric fill between devices, according to some examples. The barrier layer can remain throughout the fabrication of the integrated circuit as it does not interfere with the operation of the semiconductor devices. According to some embodiments, the barrier layer includes a metal oxide material that provides a high etch selectivity with common silicon etchants.

According to an embodiment, an integrated circuit includes a semiconductor device having a semiconductor material extending between a source region and a drain region, and a subregion adjacent to a dielectric fill. The semiconductor material is above a top surface of the dielectric fill. The semiconductor device also includes a gate layer extending over the semiconductor material and a barrier layer on the top surface of the dielectric fill. The barrier layer includes oxygen and a metal. The metal may be aluminum or titanium, to name some examples.

According to an embodiment, an integrated circuit includes a semiconductor device having a semiconductor material extending between a source region and a drain region, and a subregion adjacent to a dielectric fill. The semiconductor material is above a top surface of the dielectric fill. The semiconductor device also includes a gate structure extending over the semiconductor material and a barrier layer on the top surface of the dielectric fill. The gate structure includes a gate dielectric on the semiconductor material and a gate electrode on the gate dielectric. The gate dielectric is on the barrier layer and has a different material composition than the barrier layer.

According to another embodiment, a method of forming an integrated circuit includes forming a fin comprising semiconductor material on a substrate, the fin extending above a top surface of the substrate; forming a dielectric fill on the top surface of the substrate and around a subfin region of the fin, such that an upper portion of the fin extends above a top surface of the dielectric fill; forming a barrier layer on the top surface of the dielectric fill and on the upper portion of the fin; removing the barrier layer from the upper surface of the fin; forming a sacrificial gate over the upper surface of the fin and over the barrier layer; forming spacers along sidewalls of the sacrificial gate; forming source or drain regions on ends of the upper portion of the fin; and replacing the sacrificial gate with a gate structure.

The techniques can be used with any type of planar and non-planar transistors, including finFETs (sometimes called double-gate transistors, or tri-gate transistors), or nanowire and nanoribbon transistors (sometimes called gate-all-around transistors), to name a few examples. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of a barrier layer having both oxygen and a metal on the top surface of a dielectric fill between adjacent devices. The barrier layer may be observed sandwiched between the dielectric fill and a gate dielectric. Certain SEM or TEM cross-sections through the gate trench may also show that the dielectric fill between adjacent devices has a substantially level top surface between devices (variation of no more than 1-2 nm between devices) in comparison to other devices that do not have the barrier layer. Numerous configurations and variations will be apparent in light of this disclosure.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element (s) or feature (s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

Architecture

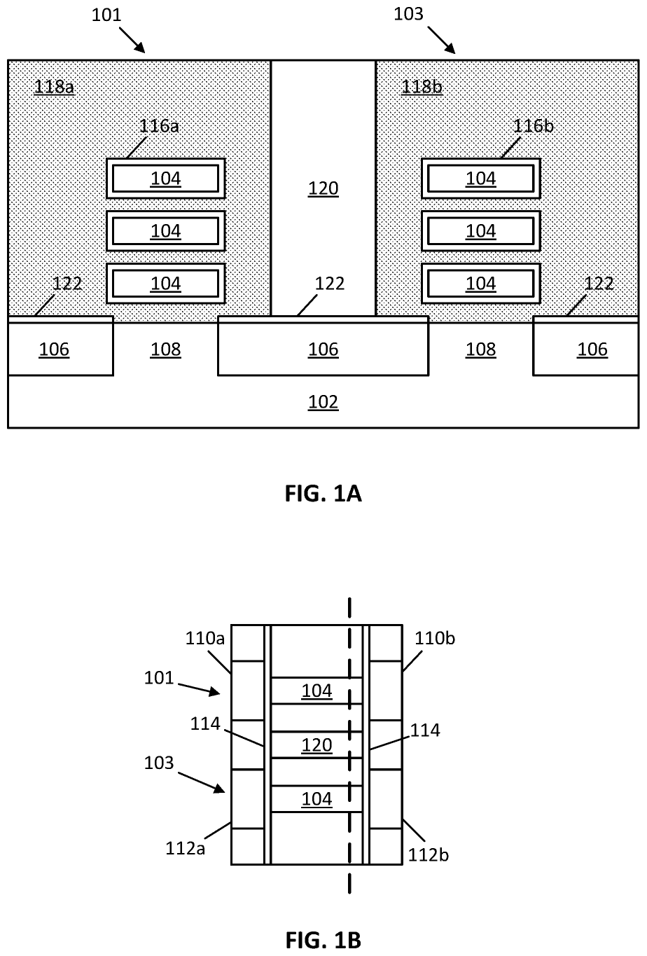

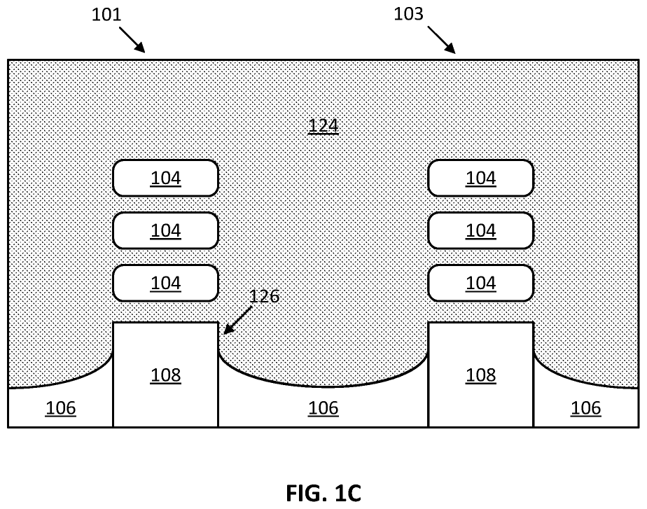

FIG. 1A is a cross sectional view taken across two example semiconductor devices 101 and 103, according to an embodiment of the present disclosure. FIG. 1B is a top-down view of the adjacent semiconductor devices 101 and 103 where FIG. 1A illustrates the cross section taken across the dashed line. It should be noted that some of the material layers (such as metal gate layers 118a and 118b) in the top-down view of FIG. 1B have been omitted for clarity. Each of semiconductor devices 101 and 103 may be non-planar metal oxide semiconductor (MOS) transistors, such as tri-gate (e.g., finFET) or gate-all-around (GAA) transistors, although other transistor topologies and types could also benefit from the techniques provided herein. The illustrated embodiments herein use the GAA structure. Semiconductor devices 101 and 103 represent a portion of an integrated circuit that may contain any number of similar semiconductor devices.

As can be seen, semiconductor devices 101 and 103 are formed on a substrate 102. Any number of semiconductor devices can be formed on substrate 102, but two are used here as an example. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 102 can be a semiconductor-on-insulator substrate having a desired semiconductor layer over a buried insulator layer (e.g., silicon over silicon dioxide). Alternatively, substrate 102 can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, a lower portion of (or all of) substrate 102 is removed and replaced with one or more backside interconnect layers to form backside signal and power routing.

Each of semiconductor devices 101 and 103 includes one or more nanoribbons 104 that extend parallel to one another along a direction between a source region and a drain region (e.g., into and out of the page in the cross-section view of FIG. 1A). Nanoribbons 104 are one example of semiconductor regions or semiconductor bodies that extend between source and drain regions. The term nanoribbon may also encompass other similar shapes such as nanowires or nanosheets. The semiconductor material of nanoribbons 104 may be formed from substrate 102. In some embodiments, semiconductor devices 101 and 103 may each include semiconductor regions in the shape of fins that can be, for example, native to substrate 102 (formed from the substrate itself), such as silicon fins etched from a bulk silicon substrate. Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of the illustrated nanoribbons 104 during a gate forming process where one type of the alternating layers is selectively etched away so as to liberate the other type of alternating layers within the channel region, so that a gate-all-around (GAA) process can then be carried out. Again, the alternating layers can be blanket deposited and then etched into fins or deposited into fin-shaped trenches.

As can further be seen, adjacent semiconductor devices are separated by a dielectric fill 106 that may include silicon oxide. Dielectric fill 106 provides shallow trench isolation (STI) between any adjacent semiconductor devices. Dielectric fill 106 can be any suitable dielectric material, such as silicon dioxide, aluminum oxide, or silicon oxycarbonitride.

Semiconductor devices 101 and 103 each include a subfin region 108. According to some embodiments, subfin region 108 comprises the same semiconductor material as substrate 102 and is adjacent to dielectric fill 106. According to some embodiments, nanoribbons 104 (or other semiconductor bodies) extend between a source and a drain region to provide an active region for a transistor (e.g., the semiconductor region beneath the gate). The source and drain regions are not shown in the cross-section of FIG. 1A, but are seen in the top-down view of FIG. 1B where nanoribbons 104 of semiconductor device 101 extend between a source region 110a and a drain region 110b (similarly, the nanoribbons 104 of semiconductor device 103 extend between a source region 112a and a drain region 112b). FIG. 1B also illustrates spacer structures 114 that extend around the ends of nanoribbons 104 and along sidewalls of the gate structures between spacer structures 114. Spacer structures 114 may include a dielectric material, such as silicon nitride.

According to some embodiments, the source and drain regions are epitaxial regions that are provided using an etch-and-replace process. In other embodiments one or both of the source and drain regions could be, for example, implantation-doped native portions of the semiconductor fins or substrate. Any semiconductor materials suitable for source and drain regions can be used (e.g., group IV and group III-V semiconductor materials). The source and drain regions may include multiple layers such as liners and capping layers to improve contact resistance. In any such cases, the composition and doping of the source and drain regions may be the same or different, depending on the polarity of the transistors. In an example, for instance, one transistor is a p-type MOS (PMOS) transistor, and the other transistor is an n-type MOS (NMOS) transistor. Any number of source and drain configurations and materials can be used.

According to some embodiments, a first gate structure extends over nanoribbons 104 of semiconductor device 101 while a second gate structure extends over nanoribbons 104 of semiconductor device 103. Each gate structure includes a respective gate dielectric 116a/116b and a gate layer 118a/118b. Gate dielectric 116a/116b represents any number of dielectric layers present between nanoribbons 104 and gate layer 118a/118b. Gate dielectric 116a/116b may also be present on the surfaces of other structures within the gate trench, such as on subfin region 108. Gate dielectric 116a/116b may include any suitable gate dielectric material(s). In some example embodiments, gate dielectric 116a/116b has a bi-layer structure that includes a first layer of native oxide material (e.g., silicon dioxide) on the nanoribbons or other semiconductor regions making up the channel region of the devices, and a second layer of high-k dielectric material (e.g., hafnium oxide or aluminum oxide) on the native oxide.

Gate layer 118a/118b may represent any number of conductive layers, such as any metal, metal alloy, or doped polysilicon layers. In some embodiments, gate layer 118a/118b includes one or more workfunction metals around nanoribbons 104. In some embodiments, one of semiconductor devices 101 and 103 is a p-channel device that include a workfunction metal having titanium around its nanoribbons 104 and the other semiconductor device is an n-channel device that includes a workfunction metal having tungsten around its nanoribbons 104. Gate layer 118a/118b may also include a fill metal or other conductive material around the workfunction metals to provide the whole gate electrode structure.

According to some embodiments, adjacent gate structures may be separated along a second direction (e.g., across the page) by a gate cut structure 120, which acts like a dielectric barrier between gate structures. Gate cut structure 120 may be formed from a sufficiently insulating material, such as a dielectric material. Example materials for gate cut structure 120 include silicon nitride, silicon oxide, or silicon oxynitride. According to some embodiments, gate cut structure 120 has a width between about 10 nm and about 15 nm.

According to some embodiments, a barrier layer 122 is present on a top surface of dielectric fill 106. Barrier layer 122 may have a thickness between about 2 nm and about 3 nm, less than 5 nm, or less than 3 nm. Barrier layer 122 includes a metal oxide material and thus contains both oxygen and a metal element, such as aluminum or titanium, according to some embodiments. Due to the timing of when barrier layer 122 is formed (as will be discussed in more detail herein), barrier layer 122 is not present on or over subfin region 108 or along sidewall portions of gate cut structure 120. Barrier layer 122 is also not present along the inner sidewalls of spacer structures 114. In some embodiments, barrier layer 122 extends beneath gate cut structure 120.

Barrier layer 122 protects the underlying dielectric fill 106 from recessing during certain fabrication processes, thus allowing a top surface of dielectric fill 106 to remain substantially level between adjacent devices 101 and 103. FIG. 1C illustrates an example of adjacent devices 101 and 103 without the use of barrier layer 122. For clarity, this example uses a single gate structure 124 across nanoribbons 104 of both devices 101 and 103. Dielectric fill 106 has recessed below the top surface of subfin regions 108, which exposes subfin portions 126 to gate structure 124. Having gate structure 124 extend below the top surfaces of subfin regions 108 creates additional parasitic capacitance and undesired carrier depletion within subfin regions 108.

Fabrication Methodology

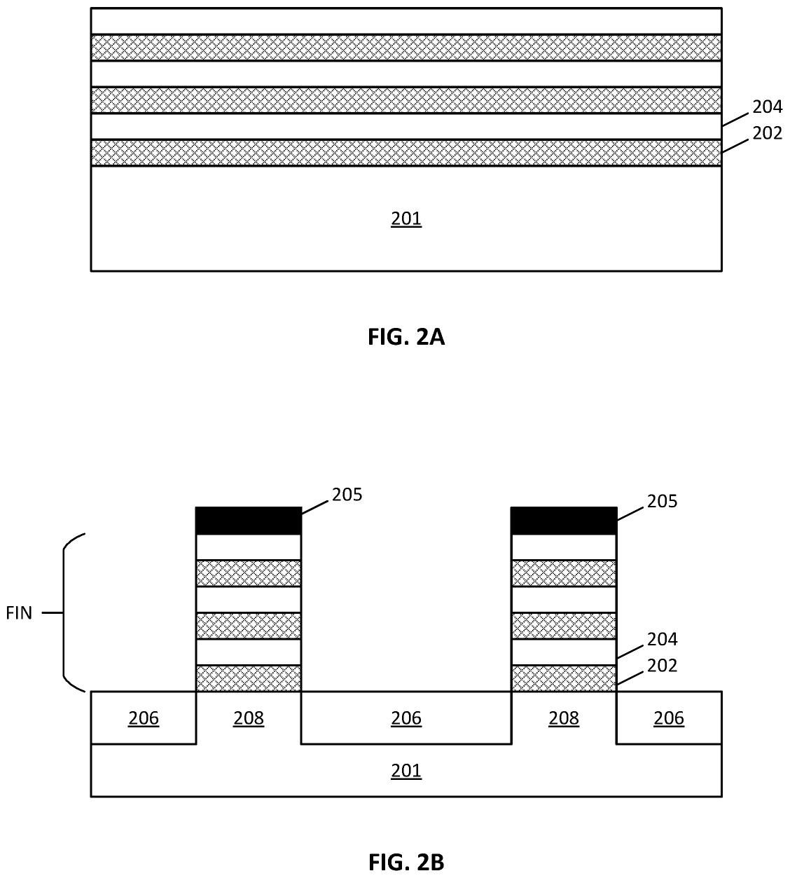

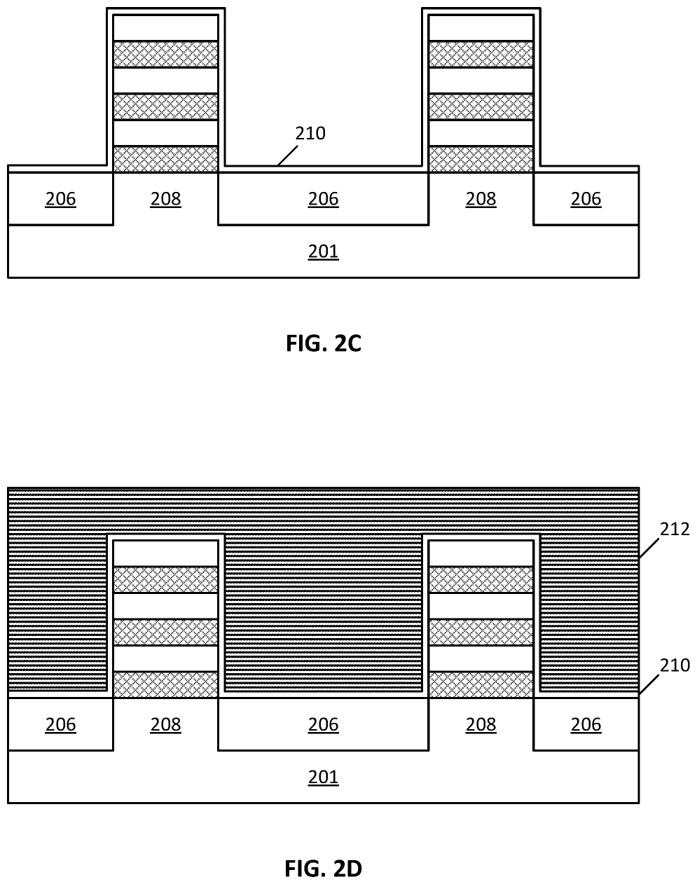

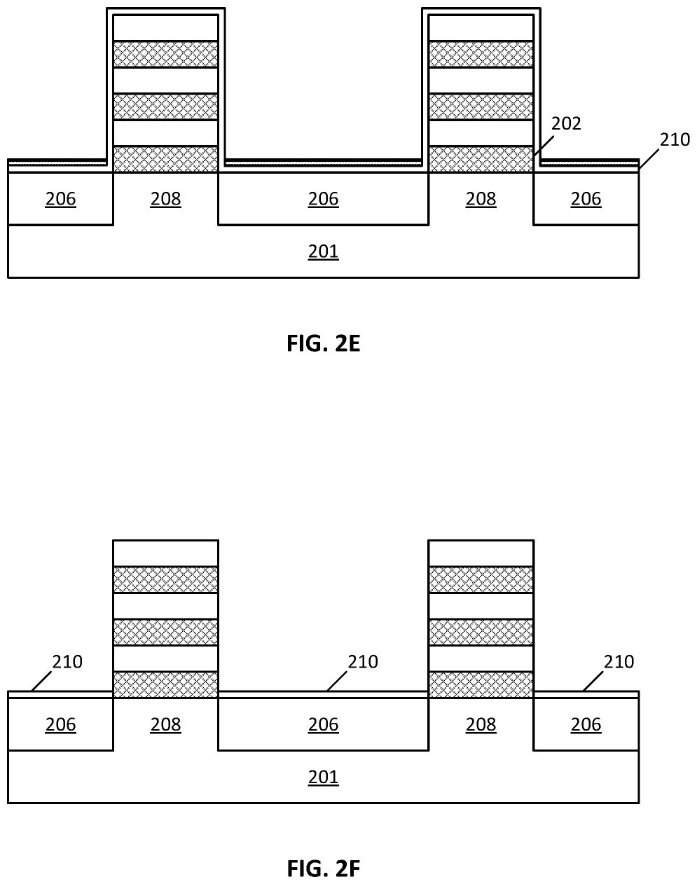

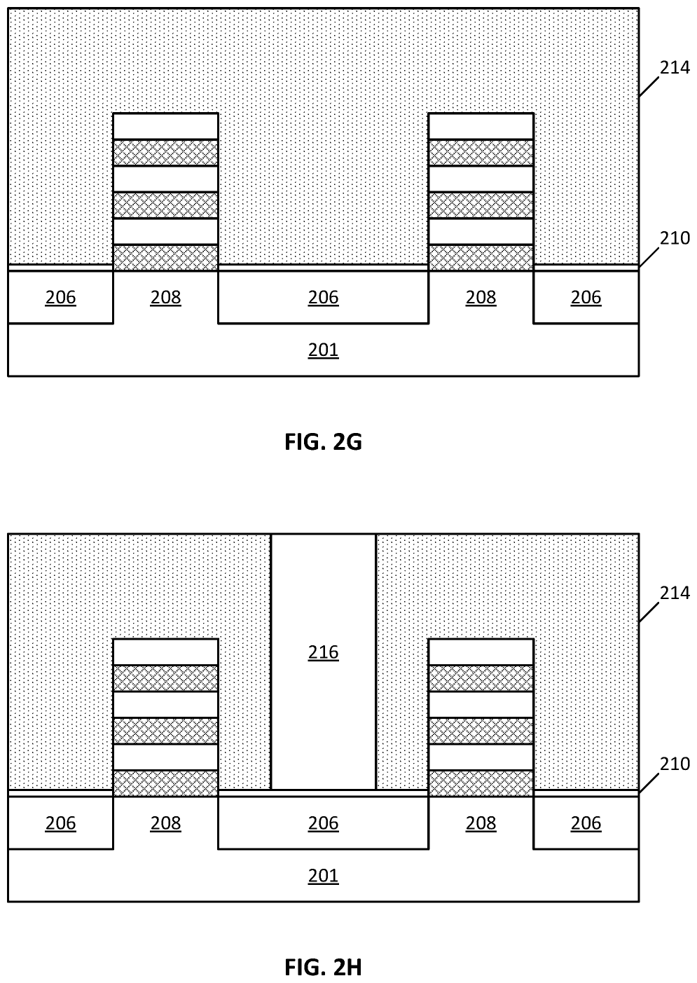

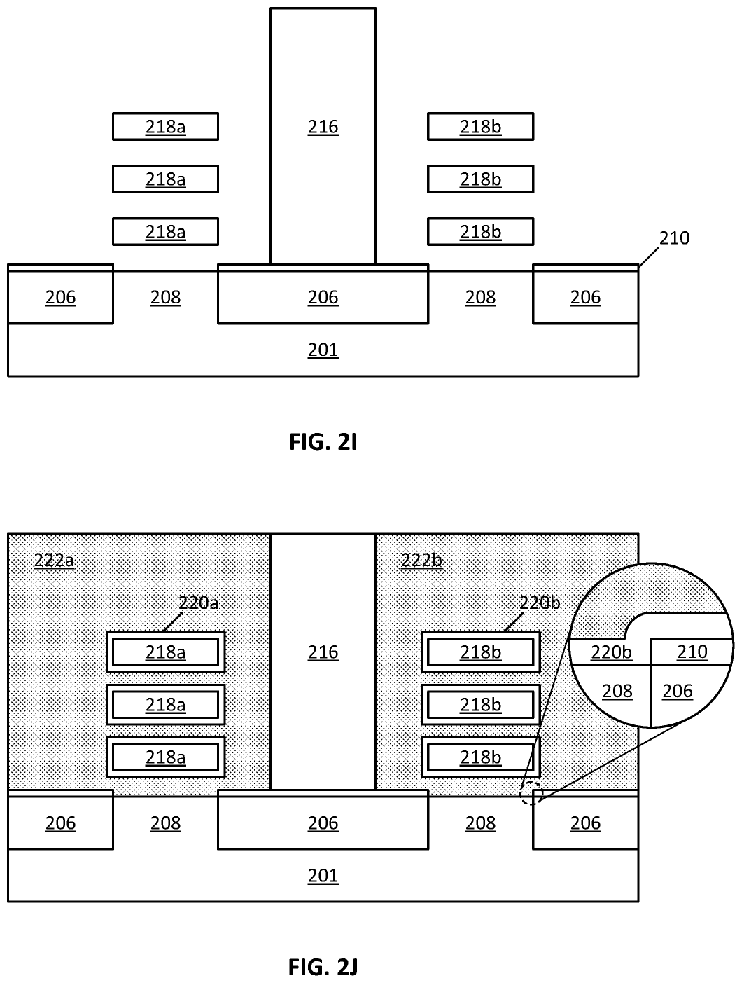

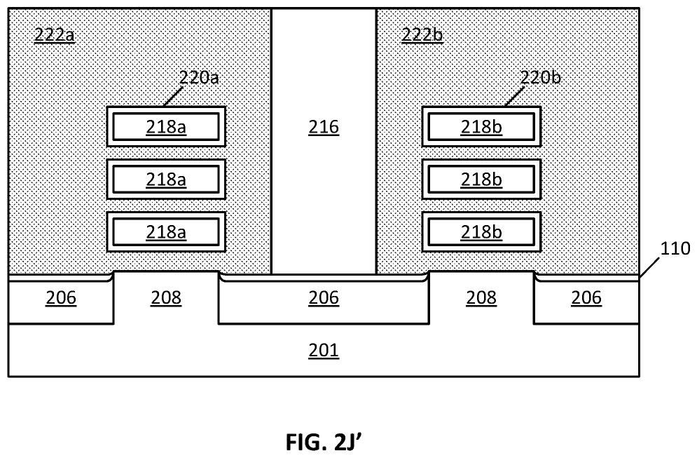

FIGS. 2A-2J′ include cross-sectional views that collectively illustrate an example process for forming an integrated circuit with semiconductor devices and a barrier layer to protect a dielectric fill from recessing between the semiconductor devices, in accordance with an embodiment of the present disclosure. Each figure shows an example structure that results from the process flow up to that point in time, so the depicted structure evolves as the process flow continues, culminating in the structure shown in FIG. 2J, which is similar to the structure shown in FIG. 1A. The illustrated integrated circuit structure may be part of a larger integrated circuit that includes other integrated circuitry not depicted. Example materials and process parameters are given, but the present disclosure is not intended to be limited to any specific such materials or parameters, as will be appreciated.

FIG. 2A illustrates a cross-sectional view taken through a substrate 201 having a series of material layers formed over the substrate, according to an embodiment of the present disclosure. Alternating material layers may be deposited over substrate 201 including sacrificial layers 202 alternating with semiconductor layers 204. The alternating layers are used to form GAA transistor structures. Any number of alternating semiconductor layers 204 and sacrificial layers 202 may be deposited over substrate 201. The description above for substrate 102 applies equally to substrate 201.

According to some embodiments, sacrificial layers 202 have a different material composition than semiconductor layers 204. In some embodiments, sacrificial layers 202 are silicon germanium (SiGe) while semiconductor layers 204 include a semiconductor material suitable for use as a nanoribbon such as silicon (Si), SiGe, germanium, or III-V materials like indium phosphide (InP) or gallium arsenide (GaAs). In examples where SiGe is used in each of sacrificial layers 202 and in semiconductor layers 204, the germanium concentration is different between sacrificial layers 202 and semiconductor layers 204. For example, sacrificial layers 202 may include a higher germanium content compared to semiconductor layers 204. In some examples, semiconductor layers 204 may be doped with either n-type dopants (to produce a p-channel transistor) or p-type dopants (to produce an n-channel transistor).

While dimensions can vary from one example embodiment to the next, the thickness of each sacrificial layer 202 may be between about 5 nm and about 20 nm. In some embodiments, the thickness of each sacrificial layer 202 is substantially the same (e.g., within 1-2 nm). The thickness of each of semiconductor layers 204 may be about the same as the thickness of each sacrificial layer 202 (e.g., about 5-20 nm). Each of sacrificial layers 202 and semiconductor layers 204 may be deposited using any known material deposition technique, such as chemical vapor deposition (CVD), plasma-enhanced chemical vapor deposition (PECVD), physical vapor deposition (PVD), or atomic layer deposition (ALD).

FIG. 2B depicts the cross-section view of the structure shown in FIG. 2A following the formation of a cap layer 205 and the subsequent formation of fins beneath cap layer 205, according to an embodiment. Cap layer 205 may be any suitable hard mask material such as a carbon hard mask (CHM) or silicon nitride. Cap layer 205 is patterned into rows to form corresponding rows of fins from the alternating layer stack of sacrificial layers 202 and semiconductor layers 204. The rows of fins extend lengthwise in a first direction (e.g., into and out of the page).

According to some embodiments, an anisotropic etching process through the layer stack continues into at least a portion of substrate 201. The etched portion of substrate 201 may be filled with a dielectric fill 206 that acts as shallow trench isolation (STI) between adjacent fins. Dielectric fill 206 may be any suitable dielectric material such as silicon oxide. Subfin regions 208 represent remaining portions of substrate 201 between dielectric fill 206, according to some embodiments.

FIG. 2C depicts the cross-section view of the structure shown in FIG. 2B following the formation of a barrier layer 210, according to an embodiment. In some embodiments, cap layer 205 has been removed using any standard etching process. In some examples, cap layer 205 remains on the fins until its removal at a later time. Barrier layer 210 may be conformally deposited over all exposed surfaces using any known CVD process, such as ALD. In some embodiments, barrier layer 210 is deposited to a final thickness between about 2 nm and about 3 nm, less than 5 nm, or less than 3 nm. Barrier layer 210 may be any material that is suitable to act as an effective etch stop for silicon-based etchants. Accordingly, barrier layer 210 may be a metal oxide material that includes oxygen and any metal element. Some example metal elements included in barrier layer 210 can include aluminum, titanium, tantalum, ruthenium, molybdenum, zinc, or cobalt.

FIG. 2D depicts the cross-section view of the structure shown in FIG. 2C following the formation of a masking layer 212, according to an embodiment. Masking layer 212 may be any suitable hard mask material that can be removed without damaging any of the semiconductor fin layers. In some examples, masking layer 212 is a carbon hard mask (CHM). Masking layer 212 may be deposited to a thickness at least above the top surface of the fins and subsequently planarized using a polishing procedure. In some embodiments, a chemical mechanical polishing (CMP) procedure is used to polish the top surface of masking layer 212.

FIG. 2E depicts the cross-section view of the structure shown in FIG. 2D following the recessing of masking layer 212, according to an embodiment. Masking layer 212 may be uniformly recessed such that it is removed from around the fins but remains on the lower horizontal surfaces (e.g., on barrier layer 210 that in turn is on dielectric fill 206). According to some embodiments, masking layer 212 is recessed to a final thickness of less then 5 nm, less than 3 nm, or less than 1 nm. In some embodiments, a top surface of masking layer 212 is recessed at least below a top surface of the lowest sacrificial layer 202 of the fins.

FIG. 2F depicts the cross-section view of the structure shown in FIG. 2E following the removal of the exposed portions of barrier layer 210 and subsequent removal of masking layer 212, according to an embodiment. Portions of barrier layer 210 that extended up sidewalls of the fins and on top surfaces of the fins are removed using any standard wet etchants. Masking layer 212 (as seen from FIG. 2E) protects portions of barrier layer 210 that remain on dielectric fill 206. Masking layer 212 may be subsequently removed using an ashing process or through the use of standard wet etchants.

FIG. 2G depicts the cross-section view of the structure shown in FIG. 2F following the formation of a sacrificial gate 214 extending across the fins in a second direction different from the first direction, according to some embodiments. Sacrificial gate 214 may extend across the fins in a second direction that is orthogonal to the first direction. According to some embodiments, the sacrificial gate material is formed in parallel strips across the integrated circuit and removed in all areas not protected by a gate masking layer. Sacrificial gate 214 may be any suitable material that can be selectively removed without damaging the semiconductor material of the fins. In some examples, sacrificial gate 214 includes polysilicon.

Following the formation of sacrificial gate 214 (and prior to replacement of sacrificial gate 214 with a metal gate), additional semiconductor device structures are formed that are not shown in these cross-sections. These additional structures include spacer structures on the edges of sacrificial gate 214 and source and drain regions on either ends of each of the fins. The formation of such structures would be well understood to a person skilled in the relevant art.

FIG. 2H depicts the cross-section view of the structure shown in FIG. 2G following the formation of a gate cut structure 216, according to some embodiments. A portion of sacrificial gate 214 may be removed using an anisotropic etching process to form a given recess for a corresponding gate cut structure 216. In some embodiments, the recess is formed through an entire thickness of sacrificial gate 214, such that the recess extends to a top surface of barrier layer 210. According to some embodiments, dielectric fill 206 is protected from the etchants used to remove the portion of sacrificial gate 214 by barrier layer 210. Accordingly, gate cut structure 216 may be formed directly on or over barrier layer 210. Any such formed recess may then be filled with one or more dielectric layers to form gate cut structure 216. Gate cut structure 216 may include any suitable dielectric material, such as silicon nitride, silicon oxide, or silicon oxynitride. In some embodiments, a top surface of gate cut structure 216 is polished using, for example, chemical mechanical polishing (CMP) to planarize the top surface of gate cut structure 216 with a top surface of at least sacrificial gate 214.

FIG. 2I depicts the cross-section view of the structure shown in FIG. 2H following the removal of sacrificial gate 214 and sacrificial layers 202, according to some embodiments. In examples where any gate masking layers are still present, they would also be removed at this time. Once sacrificial gate 214 is removed, the fins that had been beneath sacrificial gate 214 are exposed.

In the example where the fins include alternating semiconductor layers, sacrificial layers 202 are selectively removed to release nanoribbons 218a/218b that extend between corresponding source or drain regions. Each vertical set of nanoribbons 218a and 218b represents the semiconductor region of a different semiconductor device. It should be understood that nanoribbons 218a/218b may also be nanowires or nanosheets. Gate cut structure 216 remains following the removal of sacrificial gate 214. Sacrificial gate 214 and sacrificial layers 202 may be removed using the same isotropic etching process or different isotropic etching processes. According to some embodiments, dielectric fill 206 is protected from the etchants used to remove sacrificial gate 214 by barrier layer 210. Accordingly, the top surface of dielectric fill 206 remains substantially level with the top surface of subfin regions 208.

FIG. 2J depicts the cross-section view of the structure shown in FIG. 2I following the formation of gate structures and subsequent polishing, according to some embodiments. Each gate structure includes a gate dielectric 220a/220b and a conductive gate layer 222a/222b. Gate dielectric 220a/220b may be first formed around nanoribbons 218a/218b prior to the formation of gate layer 222a/222b. The gate dielectric 220a/220b may include any suitable dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 220a/220b includes a layer of hafnium oxide with a thickness between about 1 nm and about 5 nm. In some embodiments, gate dielectric 220a/220b may include one or more silicates (e.g., titanium silicate, tungsten silicate, niobium silicate, and silicates of other transition metals). In some cases, gate dielectric 220a/220b may include a first layer on nanoribbons 218a/218b, and a second layer on the first layer. The first layer can be, for instance, an oxide of the semiconductor material of nanoribbons 218a/218b (e.g., silicon dioxide) and the second layer can be a high-k dielectric material (e.g., hafnium oxide). More generally, gate dielectric 220a/220b can include any number of dielectric layers. According to some embodiments, gate dielectric 220a/220b forms along all surfaces exposed within the gate trench, such as along inner sidewalls of the spacer structures and along sides of gate cut structure 216). As seen in the zoomed-in view, gate dielectric 220a/220b may form directly on barrier layer 210 and on subfin regions 208.

As noted above, gate layer 222a/222b can represent any number of conductive layers. The conductive gate layer 222a/222b may be deposited using electroplating, electroless plating, CVD, PECVD, ALD, or PVD, to name a few examples. In some embodiments, gate layer 222a/222b includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate layer 222a/222b may include, for instance, a metal fill material along with one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates. Following the formation of the gate structures, the entire structure may be polished such that the top surface of any given gate structure is planar with the top surface of at least gate cut structure 216.

FIG. 2J′ illustrates another cross-section view of the structure shown in FIG. 2J, but with slightly recessed dielectric fill 206 regions. Dielectric fill 206 may exhibit a small recessing away from the top surface of subfin regions 208 during the formation of dielectric fill 206. However, barrier layer 110 prevents any further recessing that would expose side portions of subfin regions 208.

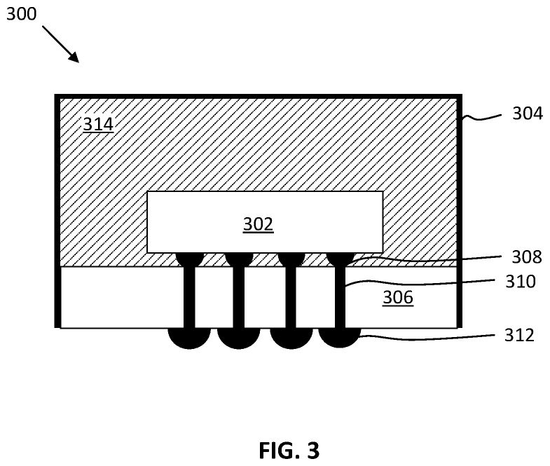

FIG. 3 illustrates an example embodiment of a chip package 300, in accordance with an embodiment of the present disclosure. As can be seen, chip package 300 includes one or more dies 302. One or more dies 302 may include at least one integrated circuit having semiconductor devices, such as any of the semiconductor devices disclosed herein. One or more dies 302 may include any other circuitry used to interface with other devices formed on the dies, or other devices connected to chip package 300, in some example configurations.

As can be further seen, chip package 300 includes a housing 304 that is bonded to a package substrate 306. The housing 304 may be any standard or proprietary housing, and may provide, for example, electromagnetic shielding and environmental protection for the components of chip package 300. The one or more dies 302 may be conductively coupled to a package substrate 306 using connections 308, which may be implemented with any number of standard or proprietary connection mechanisms, such as solder bumps, ball grid array (BGA), pins, or wire bonds, to name a few examples. Package substrate 306 may be any standard or proprietary package substrate, but in some cases includes a dielectric material having conductive pathways (e.g., including conductive vias and lines) extending through the dielectric material between the faces of package substrate 306, or between different locations on each face. In some embodiments, package substrate 306 may have a thickness less than 1 millimeter (e.g., between 0.1 millimeters and 0.5 millimeters), although any number of package geometries can be used. Additional conductive contacts 312 may be disposed at an opposite face of package substrate 306 for conductively contacting, for instance, a printed circuit board (PCB). One or more vias 310 extend through a thickness of package substrate 306 to provide conductive pathways between one or more of connections 308 to one or more of contacts 312. Vias 310 are illustrated as single straight columns through package substrate 306 for ease of illustration, although other configurations can be used (e.g., damascene, dual damascene, through-silicon via, or an interconnect structure that meanders through the thickness of substrate 306 to contact one or more intermediate locations therein). In still other embodiments, vias 310 are fabricated by multiple smaller stacked vias, or are staggered at different locations across package substrate 306. In the illustrated embodiment, contacts 312 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 312, to inhibit shorting.

In some embodiments, a mold material 314 may be disposed around the one or more dies 302 included within housing 304 (e.g., between dies 302 and package substrate 306 as an underfill material, as well as between dies 302 and housing 304 as an overfill material). Although the dimensions and qualities of the mold material 314 can vary from one embodiment to the next, in some embodiments, a thickness of mold material 314 is less than 1 millimeter. Example materials that may be used for mold material 314 include epoxy mold materials, as suitable. In some cases, the mold material 314 is thermally conductive, in addition to being electrically insulating.

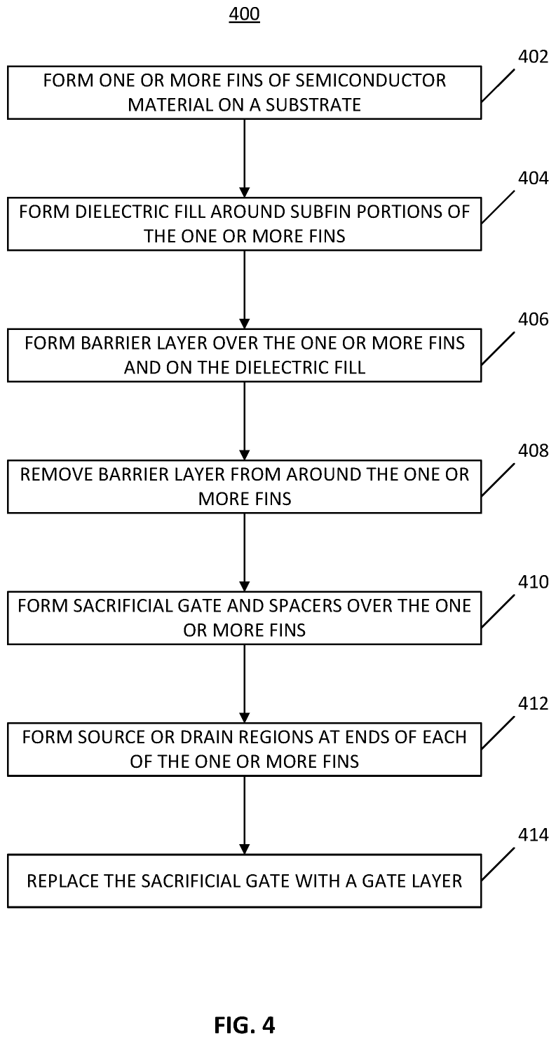

FIG. 4 is a flow chart of a method 400 for forming at least a portion of an integrated circuit, according to an embodiment. Various operations of method 400 may be illustrated in FIGS. 2A-2J′. However, the correlation of the various operations of method 400 to the specific components illustrated in the aforementioned figures is not intended to imply any structural and/or use limitations. Rather, the aforementioned figures provide one example embodiment of method 400. Other operations may be performed before, during, or after any of the operations of method 400. For example, method 400 does not explicitly describe all processes that are performed to form common transistor structures. Some of the operations of method 400 may be performed in a different order than the illustrated order.

Method 400 begins with operation 402 where a plurality of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. The alternating layers can be blanket deposited and then etched into fins, or deposited into fin-shaped trenches. The fins may also include a cap structure over each fin that is used to define the locations of the fins during, for example, an RIE process. The cap structure may be a dielectric material, such as silicon nitride.

Method 400 continues with operation 404 where a dielectric fill is formed around subfin portions of the one or more fins. In some embodiments, the dielectric fill extends between each pair of adjacent parallel fins and runs lengthwise in the same direction as the fins. The anisotropic etching process that forms the fins also etches into a portion of the substrate and the dielectric fill may be formed within the recessed portions of the substrate. Accordingly, the dielectric fill acts as shallow trench isolation (STI) between adjacent fins. The dielectric fill may be any suitable dielectric material, such as silicon oxide.

Method 400 continues with operation 406 where a barrier layer is formed over at least the dielectric fill. The barrier layer may be conformally deposited over all exposed surfaces, such as on the surfaces of the one or more fins, using any known CVD process, such as ALD. In some embodiments, the barrier layer is deposited to a final thickness between about 2 nm and about 3 nm, less than 5 nm, or less than 3 nm. The barrier layer may be any material that is suitable to act as an effective etch stop for silicon-based etchants. Accordingly, the barrier layer may be a metal oxide material that includes oxygen and any metal element. Some example metal elements included in the barrier layer can include aluminum, titanium, tantalum, ruthenium, molybdenum, zinc, or cobalt.

Method 400 continues with operation 408 where the barrier layer is removed from around the one or more fins. Portions of the barrier layer may be selectively removed by forming a masking layer over the barrier layer and recessing the masking layer to a final height that protects the portions of the barrier layer on the dielectric fill but exposes the portions of the barrier layer on the fins. The masking layer may be any suitable hard mask material, such as CHM. Once the masking layer has been recessed to its final height, the exposed portions of the barrier layer may be selectively removed using standard wet etchants. The masking layer can then also be removed, via ashing or wet etchants, such that barrier layer remains on the top surface of the dielectric fill between the fins.

Method 400 continues with operation 410 where a sacrificial gate and spacer structures are formed over the fins. The sacrificial gate may be patterned using a gate masking layer in a strip that runs orthogonally over the fins (many gate masking layers and corresponding sacrificial gates may be formed parallel to one another (e.g., forming a cross-hatch pattern with the fins). The gate masking layer may be any suitable hard mask material, such as CHM or silicon nitride. The sacrificial gate may be formed from any suitable material that can be selectively removed at a later time without damaging the semiconductor material of the fins. In one example, the sacrificial gate includes polysilicon. The spacer structures may be deposited and then etched back such that the spacer structures remain mostly only on sidewalls of any exposed structures. According to some embodiments, the spacer structures may be any suitable dielectric material, such as silicon nitride or silicon oxynitride.

Method 400 continues with operation 412 where source or drain regions are formed at the ends of the semiconductor regions of each of the fins. Any portions of the fins not protected by the sacrificial gate and spacer structures may be removed using, for example, an anisotropic etching process followed by the epitaxial growth of the source or drain regions from the exposed ends of the semiconductor layers in the fins. In some example embodiments, the source or drain regions are NMOS source or drain regions (e.g., epitaxial silicon) or PMOS source or drain regions (e.g., epitaxial SiGe). Another dielectric fill may be formed adjacent to the various source or drain regions for additional electrical isolation between adjacent regions. The dielectric fill may also extend over a top surface of the source or drain regions. In some embodiments, topside conductive contacts may be formed through the dielectric fill to contact one or more of the source or drain regions.

Method 400 continues with operation 414 where the sacrificial gate is removed and replaced with a gate structure. The sacrificial gate may be removed using an isotropic etching process that selectively removes all of the material from the sacrificial gate, thus exposing the various fins between the set of spacer structures. During this etching process, the underlying dielectric fill between the fins is protected from the etchants by the barrier layer. In the example case where GAA transistors are used, any sacrificial layers within the exposed fins between the spacer structures may also be removed to release nanoribbons, nanosheets, or nanowires of semiconductor material.

The gate structure may include both a gate dielectric and a gate layer. The gate dielectric is first formed over the exposed semiconductor regions between the spacer structures followed by forming the gate layer within the remainder of the trench between the spacer structures, according to some embodiments. The gate dielectric may include any number of dielectric layers deposited using a CVD process, such as ALD. The gate layer can include any conductive material, such as a metal, metal alloy, or polysilicon. The gate layer may be deposited using electroplating, electroless plating, CVD, ALD, PECVD, or PVD, to name a few examples.

Example System

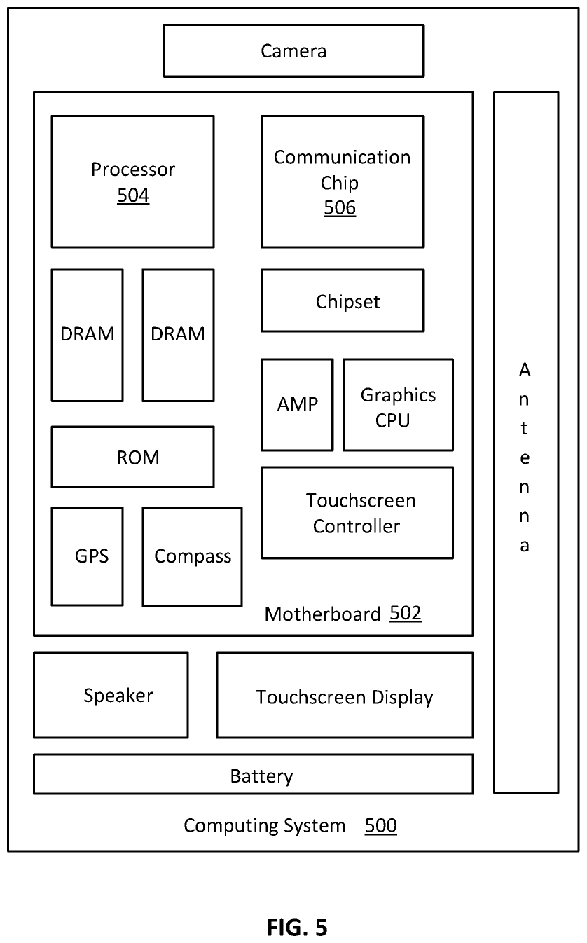

FIG. 5 is an example computing system implemented with one or more of the integrated circuit structures as disclosed herein, in accordance with some embodiments of the present disclosure. As can be seen, the computing system 500 houses a motherboard 502. The motherboard 502 may include a number of components, including, but not limited to, a processor 504 and at least one communication chip 506, each of which can be physically and electrically coupled to the motherboard 502, or otherwise integrated therein. As will be appreciated, the motherboard 502 may be, for example, any printed circuit board (PCB), whether a main board, a daughterboard mounted on a main board, or the only board of system 500, etc.

Depending on its applications, computing system 500 may include one or more other components that may or may not be physically and electrically coupled to the motherboard 502. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 500 may include one or more integrated circuit structures or devices configured in accordance with an example embodiment (e.g., a module including an integrated circuit on a substrate, the substrate having semiconductor devices and a barrier layer over a dielectric fill between devices). In some embodiments, multiple functions can be integrated into one or more chips (e.g., for instance, note that the communication chip 506 can be part of or otherwise integrated into the processor 504).

The communication chip 506 enables wireless communications for the transfer of data to and from the computing system 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing system 500 includes an integrated circuit die packaged within the processor 504. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 506 also may include an integrated circuit die packaged within the communication chip 506. In accordance with some such example embodiments, the integrated circuit die of the communication chip includes one or more semiconductor devices as variously described herein. As will be appreciated in light of this disclosure, note that multi-standard wireless capability may be integrated directly into the processor 504 (e.g., where functionality of any chips 506 is integrated into processor 504, rather than having separate communication chips). Further note that processor 504 may be a chip set having such wireless capability. In short, any number of processor 504 and/or communication chips 506 can be used. Likewise, any one chip or chip set can have multiple functions integrated therein.

In various implementations, the computing system 500 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 500 may be combined or integrated in a system-on-a-chip (SoC) architecture. In some embodiments, the components may be hardware components, firmware components, software components or any suitable combination of hardware, firmware or software.

### FURTHER EXAMPLE EMBODIMENTS

Example 1 is an integrated circuit comprising: a semiconductor material extending between a source region and a drain region; a subregion below the semiconductor material and adjacent to a dielectric fill, the semiconductor material being above a top surface of the dielectric fill; a gate structure extending over the semiconductor material, the gate structure comprising a gate dielectric and a gate electrode; and a layer on the top surface of the dielectric fill, wherein the gate dielectric is on the layer and has a different material composition than the layer. The layer may act as a barrier layer or a recess-inhibitor, as variously described herein.

Example 2 includes the integrated circuit of Example 1, wherein the semiconductor material comprises one or more nanoribbons (or nanowires or nanosheets). In another example, the semiconductor material comprises a fin.

Example 3 includes the integrated circuit of Example 2, wherein the one or more nanoribbons comprise silicon, germanium, or a combination thereof. Similar materials can be used for nanowires, nanosheets or a fin.

Example 4 includes the integrated circuit of any one of Examples 1 through 3, wherein the layer comprises a metal and oxygen.

Example 5 includes the integrated circuit of any one of Examples 1 through 4, wherein the layer comprises oxygen and any one of aluminum, titanium, tantalum, ruthenium, molybdenum, zinc, or cobalt. In one such example, the layer comprises oxygen and oxygen and any one of aluminum, titanium, or zinc.

Example 6 includes the integrated circuit of any one of Examples 1 through 5, wherein the semiconductor material, source region drain region, and gate structure are part of a first semiconductor device, and the integrated circuit further includes a gate cut through a portion of the gate structure, the gate cut interrupting the gate structure between the first semiconductor device and another adjacent semiconductor device, wherein the gate cut comprises a dielectric material.

Example 7 includes the integrated circuit of Example 6, wherein the gate cut is on the layer.

Example 8 includes the integrated circuit of Example 6 or 7, wherein the layer does not extend up any sidewall of the gate cut.

Example 9 includes the integrated circuit of any one of Examples 1 through 8, wherein the gate dielectric comprises high-k dielectric material. In some such cases, the gate dielectric includes a bi-layer structure and one of the layers includes high-k dielectric material.

Example 10 is a printed circuit board comprising the integrated circuit of any one of Examples 1 through 10.

Example 11 is an integrated circuit comprising: a semiconductor device having a semiconductor material extending between a source region and a drain region, a subregion adjacent to a dielectric fill, and a gate structure extending over the semiconductor material, the semiconductor material being above a top surface of the dielectric fill; and a barrier layer on the top surface of the dielectric fill, the barrier layer comprising oxygen and a metal.

Example 12 includes the integrated circuit of Example 11, wherein the semiconductor material comprises one or more nanoribbons.

Example 13 includes the integrated circuit of Example 12, wherein the one or more nanoribbons comprise silicon, germanium, or a combination thereof.

Example 14 includes the integrated circuit of any one of Examples 11 through 13, wherein the metal of the barrier layer comprises aluminum.

Example 15 includes the integrated circuit of any one of Examples 11 through 14, wherein the gate structure comprises a gate electrode and a gate dielectric, the gate dielectric being on the semiconductor material and the gate electrode being on the gate dielectric. The gate dielectric may be a bi-layer structure as described above, or otherwise have multiple layers.

Example 16 includes the integrated circuit of Example 15, wherein the gate dielectric is on the barrier layer.

Example 17 includes the integrated circuit of any one of Examples 11 through 16, and further includes a gate cut structure, the gate cut structure interrupting the gate structure between the semiconductor device and another adjacent semiconductor device, wherein the gate cut structure comprises a dielectric material.

Example 18 includes the integrated circuit of Example 17, wherein the gate cut structure is on the barrier layer.

Example 19 includes the integrated circuit of Example 17 or 18, wherein the barrier layer does not extend up any sidewall of the gate cut structure.

Example 20 is a printed circuit board comprising the integrated circuit of any one of Examples 11 through 19.

Example 21 is an electronic device that includes a chip package comprising one or more dies. At least one of the one or more dies includes: a semiconductor device having a semiconductor material extending between a source region and a drain region, a subregion adjacent to a dielectric fill, and a gate structure extending over the semiconductor material, the semiconductor material being above a top surface of the dielectric fill; and a barrier layer on the top surface of the dielectric fill, the barrier layer comprising oxygen and a metal.

Example 22 includes the electronic device of Example 21, wherein the semiconductor material comprises one or more nanoribbons.

Example 23 includes the electronic device of Example 21 or 22, wherein the one or more nanoribbons comprise silicon, germanium, or a combination thereof.

Example 24 includes the electronic device of any one of Examples 21 through 23, wherein the metal of the barrier layer comprises aluminum.

Example 25 includes the electronic device of any one of Examples 21 through 24, wherein the gate structure comprises a gate electrode and a gate dielectric, the gate dielectric being on the semiconductor material and the gate electrode being on the gate dielectric.

Example 26 includes the electronic device of Example 25, wherein the gate dielectric is on the barrier layer. As described above, the gate dielectric can be a multilayer structure.

Example 27 includes the electronic device of any one of Examples 21 through 25, wherein the at least one of the one or more dies further comprises a gate cut structure, the gate cut structure interrupting the gate structure between the semiconductor device and another adjacent semiconductor device, wherein the gate cut structure comprises a dielectric material.

Example 28 includes the electronic device of Example 27, wherein the gate cut structure is on the barrier layer.

Example 29 includes the electronic device of Example 27 or 28, wherein the barrier layer does not extend up any sidewall of the gate cut structure.

Example 30 includes the electronic device of any one of Examples 21 through 29, and further includes a printed circuit board, wherein the chip package is attached to the printed circuit board.

Example 31 is a method of forming an integrated circuit. The method includes: forming a fin comprising semiconductor material on a substrate, the fin extending above a top surface of the substrate; forming a dielectric fill on the top surface of the substrate and around a subfin region of the fin, such that an upper portion of the fin extends above a top surface of the dielectric fill; forming a barrier layer on the top surface of the dielectric fill and on the upper portion of the fin; removing the barrier layer from the upper portion of the fin; forming a sacrificial gate over the upper portion of the fin and over the barrier layer; forming spacers along sidewalls of the sacrificial gate; forming source or drain regions on ends of the upper portion of the fin; and replacing the sacrificial gate with a gate structure.

Example 32 includes the method of Example 31, and further includes forming a masking layer on the barrier layer over the top surface of the dielectric fill and over the upper portion of the fin; removing the masking layer from around the upper portion of the fin, such that the masking layer remains on the barrier layer over the top surface of the dielectric fill; and removing the masking layer on the barrier layer over the top surface of the dielectric fill following the removal of the barrier layer from the upper surface of the fin.

Example 33 includes the method of Example 31 or 32, wherein the barrier layer comprises oxygen and a metal.

Example 33 includes the method of any one of Examples 31 through 33, wherein replacing the sacrificial gate comprises: forming a gate dielectric on the barrier layer and on the semiconductor material; and forming a gate electrode on the gate dielectric.

Example 34 includes the method of any one of Examples 31 through 33, and further includes forming a gate cut through a portion of the sacrificial gate and adjacent to the upper portion of the fin, wherein the gate cut comprises a dielectric material and is formed on the barrier layer.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a semiconductor material extending between a source region and a drain region;
a subregion below the semiconductor material and adjacent to a dielectric fill, the semiconductor material being above a top surface of the dielectric fill;
a gate structure extending over the semiconductor material, the gate structure comprising a gate dielectric and a gate electrode; and
a layer on the top surface of the dielectric fill, wherein the gate dielectric is on the layer and has a different material composition than the layer.

2. The integrated circuit of claim 1, wherein the semiconductor material comprises one or more nanoribbons.

3. The integrated circuit of claim 2, wherein the one or more nanoribbons comprise silicon, germanium, or a combination thereof.

4. The integrated circuit of claim 1, wherein the layer comprises a metal and oxygen.

5. The integrated circuit of claim 1, wherein the layer comprises oxygen and any one of aluminum, titanium, or zinc.

6. The integrated circuit of claim 1, wherein the semiconductor material, source region drain region, and gate structure are part of a first semiconductor device, the integrated circuit further including a gate cut through a portion of the gate structure, the gate cut interrupting the gate structure between the first semiconductor device and another adjacent semiconductor device, wherein the gate cut comprises a dielectric material.

7. The integrated circuit of claim 6, wherein the gate cut is on the layer.

8. The integrated circuit of claim 6, wherein the layer does not extend up any sidewall of the gate cut.

9. The integrated circuit of claim 1, wherein the gate dielectric comprises high-k dielectric material.

10. A printed circuit board comprising the integrated circuit of claim 1.

11. An integrated circuit comprising:
a semiconductor device having a semiconductor material extending between a source region and a drain region, a subregion adjacent to a dielectric fill, and a gate structure extending over the semiconductor material, the semiconductor material being above a top surface of the dielectric fill; and
a barrier layer on the top surface of the dielectric fill, the barrier layer comprising oxygen and a metal.

12. The integrated circuit of claim 11, wherein the semiconductor material comprises one or more nanoribbons.

13. The integrated circuit of claim 11, wherein the metal of the barrier layer comprises aluminum.

14. The integrated circuit of claim 11, wherein the gate structure comprises a gate electrode and a gate dielectric, the gate dielectric being on the semiconductor material and the gate electrode being on the gate dielectric, and wherein the gate dielectric is on the barrier layer.

15. The integrated circuit of claim 11, further comprising a gate cut structure, the gate cut structure interrupting the gate structure between the semiconductor device and another adjacent semiconductor device, wherein the gate cut structure comprises a dielectric material, wherein the gate cut structure is on the barrier layer, and wherein the barrier layer does not extend up any sidewall of the gate cut structure.

16. An electronic device, comprising:
a chip package comprising one or more dies, at least one of the one or more dies comprising
a semiconductor device having a semiconductor material extending between a source region and a drain region, a subregion adjacent to a dielectric fill, and a gate structure extending over the semiconductor material, the semiconductor material being above a top surface of the dielectric fill; and
a barrier layer on the top surface of the dielectric fill, the barrier layer comprising oxygen and a metal.

17. The electronic device of claim 16, wherein the metal of the barrier layer comprises aluminum.

18. The electronic device of claim 16, wherein the gate structure comprises a gate electrode and a gate dielectric, the gate dielectric being on the semiconductor material and the gate electrode being on the gate dielectric, and wherein the gate dielectric is on the barrier layer.

19. The electronic device of claim 16, wherein the at least one of the one or more dies further comprises a gate cut structure, the gate cut structure interrupting the gate structure between the semiconductor device and another adjacent semiconductor device, wherein the gate cut structure comprises a dielectric material.

20. The electronic device of claim 19, wherein the gate cut structure is on the barrier layer, and wherein the barrier layer does not extend up any sidewall of the gate cut structure.
